(19) United States
(12) Patent Application Publication
(10) Pub. No.: US 2024/0164158 A1
(43) Pub. Date: May 16, 2024

(54) DISPLAY PANEL AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventors: Jingyuan HU, Shenzhen (CN); Fanjing WU, Shenzhen (CN)

(21) Appl. No.: 18/084,772

(22) Filed: Dec. 20, 2022

(30) Foreign Application Priority Data
Nov. 16, 2022 (CN) 202211435980.9

(51) Int. Cl. H10K 59/131; H01L 23/00; H10K 50/818; H10K 71/00

(52) U.S. Cl. CPC H01L 27/3276; H01L 24/05; H01L 51/5218; H01L 51/56; H01L 2227/323

(57) ABSTRACT

A display panel and a manufacturing method thereof are provided. The display panel includes a substrate, a TFT structure, a bonding line, a bonding pad, and a luminescent functional layer. The substrate includes a display area and a pad area. The TFT structure is disposed on the substrate in the display area. The bonding line is disposed on the substrate in the pad area. The bonding pad is disposed on a side of the bonding line away from the substrate. The bonding pad includes a thin film for blocking moisture and oxygen. The luminescent functional layer is disposed on a side of the TFT structure away from the substrate. The thin film for blocking moisture and oxygen is disposed on the bonding line, thereby blocking moisture and oxygen from corroding the bonding line.

### CROSS REFERENCE TO RELATED APPLICATIONS

This application claims the benefit of priority of Chinese Application No. 202211435980.9 filed on Nov. 16, 2022. The contents of the above application is incorporated by reference as if fully set forth herein in its entirety.

### FIELD

The present disclosure relates to a field of display technologies, and more particularly, to a display panel and a manufacturing method thereof.

### BACKGROUND

Organic light-emitting diode (OLED) display panels are self-luminous panels and have advantages such as fast response times, high luminescent efficiency, high brightness, and wide viewing angles. Because metal material including copper has improved conductivity, bonding lines of conventional OLED display panel products are typically made of metal material including copper. However, metal material including copper is easy to be oxidized, which affects conductivity. Therefore, bonding lines made of metal material including copper cannot be used as a metal pad directly.

Therefore, how to prevent bonding lines from being oxidized is an urgent technical issue to be solved.

### SUMMARY

Embodiments of the present disclosure provide a display panel and a manufacturing method thereof to solve a technical issue of bonding lines easy to be oxidized.

An embodiment of the present disclosure provides a display panel, comprising:
a substrate, comprising a display area and a pad area;
a thin-film transistor (TFT) structure disposed on the substrate, wherein the TFT structure is located in the display area;
a bonding line disposed on the substrate, wherein the bonding line is located in the pad area;
a bonding pad disposed on a side of the bonding line away from the substrate, wherein the bonding pad comprises a thin film for blocking moisture and oxygen; and
a luminescent functional layer disposed on a side of the TFT structure away from the substrate.

Optionally, in some embodiments provided by the present disclosure, the luminescent functional layer comprises an anode layer, the anode layer is connected to the TFT structure, and the anode layer and the bonding pad have same material.

Optionally, in some embodiments provided by the present disclosure, the bonding pad a comprises first bonding part, a second bonding part, and a third bonding part, the first bonding part is disposed on a side of the bonding line close to the TFT structure, the second bonding part is disposed on a side of the first bonding part away from the bonding line, the thin film for blocking moisture and oxygen is disposed on a side of the second bonding part away from the first bonding part, the third bonding part is disposed on a side of the thin film for blocking moisture and oxygen away from the second bonding part, and the anode layer comprises a first anode sub-layer, a second anode sub-layer, a thin film for insulating moisture and oxygen, and a third anode sub-layer sequentially disposed on the TFT structure.

Optionally, in some embodiments provided by the present disclosure, an orthographic projection of first anode sub-layer on the substrate covers an orthographic projection of the second anode sub-layer on the substrate.

Optionally, in some embodiments provided by the present disclosure, the first bonding part and the first anode sub-layer comprise same material, the material of the first bonding part comprises one of indium tin oxide, indium zinc oxide, Mo, Ni, Nb, or Ti.

Optionally, in some embodiments provided by the present disclosure, the second bonding part and the second anode sub-layer comprise same material, and the material of the second bonding part comprises a mixture of Al, Ni, Cu, and LA, or comprises an Al alloy.

Optionally, in some embodiments provided by the present disclosure, the third anode sub-layer and the third bonding part comprise same material, and the material of the third bonding part comprises indium tin oxide.

Optionally, in some embodiments provided by the present disclosure, the material of the thin film for blocking moisture and oxygen and the material of the thin film for insulating moisture and oxygen comprise metal oxide.

Optionally, in some embodiments provided by the present disclosure, the display panel comprises a passivation layer, a planarization layer, a first opening, and a second opening, the passivation layer is disposed on the substrate, the planarization layer Is disposed on a side of the passivation layer away from the substrate, the first opening penetrates the passivation layer and exposes at least part of a surface of the bonding line away from the substrate, the bonding pad is connected to the bonding line by the first opening, the second opening penetrates the planarization layer and the passivation layer and exposes part of a surface of the TFT structure, and the anode layer is connected to the TFT structure by the second opening.

Optionally, in some embodiments provided by the present disclosure, the TFT structure comprises an active layer, a gate, a source, and a gate, the bonding line, the source, and the drain are disposed on a same layer.

Correspondingly, the present disclosure provides a method of manufacturing a display panel, comprising a plurality of following steps:
providing a substrate, wherein the substrate comprises a display area and a pad area;
forming a thin-film transistor (TFT) structure and bonding line on the substrate, wherein the TFT structure is located in the display panel, and the bonding line is located in the pad area; and
forming a bonding pad and a luminescent functional layer on the substrate, wherein the bonding pad is disposed on the bonding line, the bonding pad comprises a thin film for blocking moisture and oxygen, and the luminescent functional layer is disposed on the TFT structure.

Optionally, in some embodiments provided by the present disclosure, the luminescent functional layer comprises an anode layer, and the step of forming the bonding pad and the luminescent functional layer comprises a following step:

forming the anode layer and the bonding pad on the substrate by a single mask process, wherein the anode layer is connected to the TFT structure, the bonding pad is disposed on a side of the bonding line away from the substrate, the bonding pad comprises a first bonding part, a second bonding part, and the third bonding part, the anode layer comprises a first anode sub-layer, a second anode sub-layer, a thin film for insulating moisture and oxygen, and a third anode sub-layer sequentially disposed on the TFT structure.

Optionally, in some embodiments provided by the present disclosure, the step of forming the anode layer and the bonding pad on the substrate by the single mask process comprises a plurality of following steps:
sequentially forming a first conductive metal layer and a second conductive metal layer on the substrate;
oxidizing a surface of the second conductive metal layer away from the first conductive metal layer to form a blocking layer;
forming a third conductive metal layer on the blocking layer;
processing the first conductive metal layer, the second conductive metal layer, the blocking layer, and the third conductive blocking layer by a single mask process to form the first anode sub-layer, the second anode sub-layer, the thin film for blocking moisture and oxygen, and the third anode sub-layer sequentially stacked on the thin-film structure and the first bonding part, the second bonding part, the thin-film for insulating moisture and oxygen, and the third bonding part sequentially stacked on the bonding line.

Embodiments of the present disclosure provide a display panel and a manufacturing method thereof. The display panel includes a substrate, a TFT structure, a bonding line, a bonding pad, and a luminescent functional layer. The substrate includes a display area and a pad area. The TFT structure is disposed on the substrate in the display area. The bonding line is disposed on the substrate in the pad area. The bonding pad is disposed on a side of the bonding line away from the substrate. The bonding pad includes a thin film for blocking moisture and oxygen. The luminescent functional layer is disposed on a side of the TFT structure away from the substrate. The bonding line is commonly made of metal material, and is easy to be oxidized, which affects conductivity performance. Therefore, the bonding line cannot be directly used as a metal pad. In the embodiments provided by the present disclosure, the thin film for blocking moisture and oxygen is disposed on the bonding line, thereby blocking moisture and oxygen from corroding the bonding line.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a first structural schematic view showing a display panel provided by an embodiment of the present disclosure.

FIG. 2 is a second structural schematic view showing a display panel provided by an embodiment of the present disclosure.

FIG. 3 is a flowchart showing steps of a method of manufacturing a display panel provided by an embodiment of the present disclosure.

FIG. 4 is a schematic view showing the method of manufacturing the display panel provided by the embodiment of the present disclosure.

### DETAILED DESCRIPTION

To illustrate goals, technical solutions, and advantages of the present disclosure more clearly, embodiments are described in detail in conjunction with accompanying drawings, wherein the identical or similar reference numerals constantly denote the identical or similar elements or elements having the identical or similar functions. The specific embodiments described with reference to the attached drawings are all exemplary and are intended to illustrate and interpret the present disclosure, which shall not be construed as causing limitations to the present disclosure. A wording “embodiment” used in the present disclosure means an example or a demonstration.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

Embodiments of the present disclosure provide a display panel and a manufacturing method thereof which are described in detail below. It should be noted that a description order of the following embodiments does not limit a preferred order of the embodiments.

The display panel provided by the present disclosure is described in detail as follows in conjunction with specific embodiments.

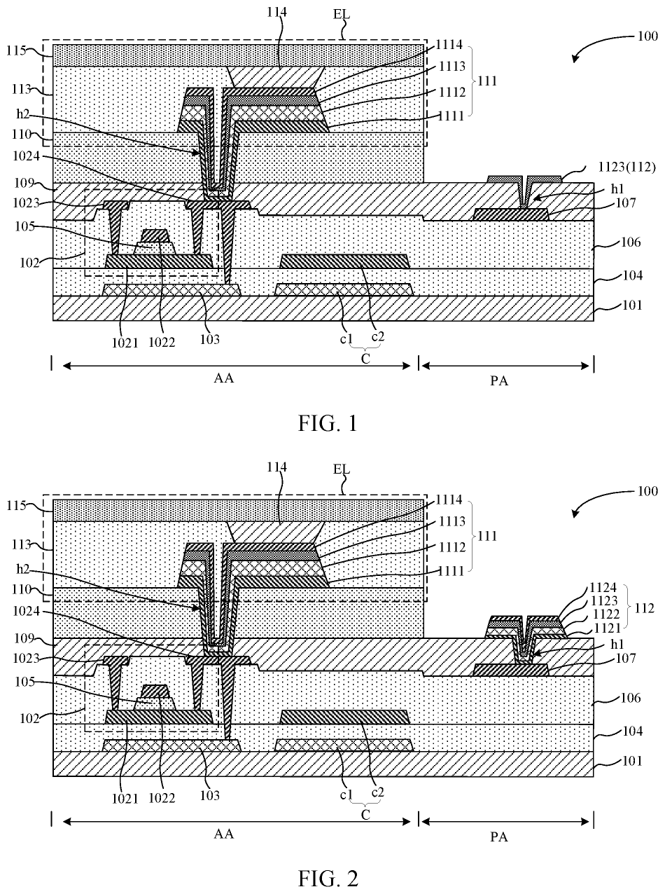

Please refer to FIG. 1. FIG. 1 is a first structural schematic view showing a display panel provided by an embodiment of the present disclosure. The present embodiment provides a display panel 100. The display panel 100 includes a substrate 101, a thin-film transistor (TFT) structure 102, a bonding line 107, a bonding pad 112, and a luminescent functional layer EL. The substrate 101 includes a display area AA and a pad area PA. The TFT structure 102 is disposed on the substrate 101 in the pad area PA. The bonding pad 112 is disposed on a side of the bonding line 107 away from the substrate 101. The bonding pad 112 includes a thin film 1123 for blocking moisture and oxygen disposed on the bonding line 107. The luminescent functional layer EL is disposed on a side of the TFT structure 102 away from the substrate 101. In the present embodiment, the thin film 1123 for blocking moisture and oxygen is disposed on the bonding line 107 to block moisture and oxygen from corroding the bonding line 107.

Please refer to FIG. 2. FIG. 2 is a second structural schematic view showing a display panel provided by an embodiment of the present disclosure. The present embodiment provides a display panel 100. The display panel 100 includes a substrate 101, a TFT structure 102, a bonding line 107, a bonding pad 112, and a luminescent functional layer EL. The substrate 101 includes a display area AA and a pad area PA. The TFT structure 102 is disposed on the substrate 101 in the display area AA. The bonding line 107 is disposed on the substrate 101 in the pad area PA. The bonding pad 112 is disposed on a side of the bonding line 107 away from the substrate 101. The bonding pad 112 includes a first bonding part 1121, a second bonding part 1122, a thin film 1123 for blocking moisture and oxygen, and a third bonding part 1124 sequentially disposed on the bonding line 107. The luminescent functional layer EL is disposed on a side of the TFT structure 102 away from the substrate 101.

In the present embodiment, the boning pad 112 includes the thin film 1123 for blocking moisture and oxygen. The thin film 1123 for blocking moisture and oxygen is disposed on the bonding line 107 to block moisture and oxygen from corroding the bonding line 107. In addition, an anode layer 111 and the bonding pad 112 can be formed by a single mask process. Therefore, steps of manufacturing the display panel 100 can be simplified, and manufacturing cost of the display panel can be reduced.

Moreover, the luminescent functional layer EL includes the anode layer 111. The anode layer 111 is connected to the TFT structure 102. The anode layer 111 and the bonding pad 112 have same material. The anode layer 111 and the bonding pad 112 can be formed by a single mask process. Therefore, steps of forming the display panel 100 are simplified, and manufacturing cost of the display panel is reduced.

The display panel 100 includes a light-shielding layer 103, a buffer layer 104, a gate insulating layer 105, an interlayer dielectric layer 106, a passivation layer 109, a planarization layer 110, a first opening h1, and a second opening h2. The TFT structure 102 includes an active layer 1021, a gate 1022, a source 1023, and a drain 1024. The bonding line 107, the source 1023, and the drain 1024 are disposed on a same layer.

It should be noted that “same layer” is a layer structure formed by a single patterning process with a single mask plate after using a film-manufacturing process to form a film configured to form a specific pattern. The single patterning process may include a plurality of exposure processes, a plurality of developing processes, and a plurality of etching processes according to different patterns. The specific pattern of the layer structure may be continuous or non-continuous. Multiple specific patterns may have different heights and different thicknesses.

In some embodiments, the light-shielding layer 103 is disposed on the substrate 101. Material of the light-shielding layer 103 may be at least one of Mo, Ti, Cu, or Mn.

The buffer layer 104 is disposed on the substrate 101 and covers the light-shielding layer 103. Material of the buffer layer 104 may be at least one of silicon oxide, silicon nitride, or silicon oxynitride.

The active layer 1021 is disposed on a side of the buffer layer 104 away from the substrate 101. Material of the active layer 1021 may be one of indium gallium zinc oxide, indium gallium tin oxide, or indium gallium zinc tin oxide. Alternatively, the active layer 1021 may also be a low-temperature polysilicon active layer or an amorphous silicon (a-Si) active layer.

Because oxide thin film transistors (OTFTs) have advantages, such as high charge carrier mobility, low power consumption, and a capability to be used in low-frequency driving, they become a mainstream of a TFT field. In the OTFTs, the active layer 1021 of TFTs is formed of metal oxide semiconductors. In the present disclosure, material of the active layer 1021 is metal oxide, thereby improving a driving capability of driver substrates.

The gate insulating layer 105 is disposed on a side of the active layer 1021 away from the buffer layer 104. Material of the gate insulating layer 105 may be at least one of silicon oxide, silicon nitride, or silicon oxynitride.

The gate 1022 is disposed on a side of the gate insulating layer 105 away from the active layer 1021. Material of the gate 1022 may be one of Mo, Ti, or Cu, or may be alloy material.

The interlayer dielectric layer 106 is disposed on a side of the gate 1022 away from the gate insulating layer 105. Material of the interlayer dielectric layer 106 may be at least one of silicon oxide, silicon nitride, or silicon oxynitride.

The source 1023, the drain 1024, and the bonding line 107 are spacedly disposed on the interlayer dielectric layer 106. Material of the source 1023, the drain 1024, and the bonding line 107 may be one of Mo, Ti, Cu, or Mn, or may be alloy material.

The drain 1024 is connected to the light-shielding layer 103. In the present embodiment, the light-shielding layer 103 not only can block light from being emitted on the active layer 1021 but also can prevent stability of the active layer 1021 from being affected due to irradiation. Moreover, the light-shielding layer 103 is electrically connected to the drain 1024. Because an orthographic projection of the light-shielding layer 103, an orthographic projection of the active layer 1021, and an orthographic projection of the gate 1022 overlap with each other on the substrate 101, parasitic capacitance is generated between the light-shielding layer 103, the active layer 1021, and the gate 1022. When the display panel 100 works, a voltage applied to the drain 1024 may change due to different voltages applied to a data signal line. Therefore, a voltage applied to the light-shielding layer 103 may also change, which affects electric performance of the active layer 103. By connecting the light-shielding layer 103 with the source 1023 to make them have a same electric potential, electric performance of the active layer 1021 can be prevented from being affected due to changes in a voltage applied to the light-shielding layer 103.

The passivation layer 109 is disposed on a side of the interlayer dielectric layer 106 away from the gate insulating layer 105. The first opening h1 penetrates the passivation layer 109. The bonding pad 112 is connected to the bonding line 107 by the first opening h1. Material of the passivation layer 109 may be at least one of silicon oxide, silicon nitride, or silicon oxynitride.

The planarization layer 110 is disposed on a side of the passivation layer 109 away from the interlayer dielectric layer 106 in the display area AA. The second opening h2 penetrates the planarization layer 110 and the passivation layer 109. The anode layer 111 is connected to the drain 1024 by the second opening h2. Material of the planarization layer 110 may be an organic resin.

In the present embodiment, it should be noted that the TFT structure 102 may be a top-gate TFT structure or a bottom-gate TFT structure. In the present embodiment, the top-gate TFT structure is taken as an example, but is not limited thereto.

The first bonding part 1121 is disposed on a side of the bonding line 107 away from the TFT structure 102. The second bonding part 1122 is disposed on a side of the first bonding part 1121 away from the bonding line 107. The third bonding part 1124 is disposed on a side of the thin-film 1123 for blocking moisture and oxygen away from the second bonding part 1122.

In some embodiments, the thin film 1123 for blocking moisture and oxygen is formed by contacting a surface of the first bonding part 1121 with oxygen. That is, formation of the thin film 1123 for blocking moisture and oxygen is relative to material properties of the second bonding part 1122. The second bonding part 1122 includes dens metal oxide formed in an oxygen environment, and has a capability to block moisture and oxygen without affecting conductivity performance of a metal pad.

In some embodiments, the thin film 1123 for blocking moisture and oxygen includes an aluminum oxide thin film. In the present embodiment, the thin film 1123 for blocking moisture and oxygen is formed by contacting a surface of the second bonding part 1122 away from the first bonding part 1121 with oxygen. The thin film 1123 for blocking moisture and oxygen is configured to prevent oxygen from further entering the display panel 100 from bottom layers to corrode the bonding line 107.

In some embodiments, a thickness of the thin film 1123 for blocking moisture and oxygen is less than 500 Å. For example, the thickness of the thin film 1123 for blocking moisture and oxygen may be 50 Å, 100 Å, 150 Å, 200 Å, 300 Å, 550 Å, or 500 Å. In the present embodiment, the thickness of the thin film 1123 for blocking moisture and oxygen is set to be less than 500 Å. Therefore, the thin film 1123 for blocking moisture and oxygen may have a capability to block moisture and oxygen from entering the display panel 100 from bottom layers to corrode the bonding line 107 without affecting conductivity performance of the bonding pad 112.

In the present embodiment, it should be noted that because the thin film 1123 for blocking moisture and oxygen is very thin, when the second bonding part 1122 and the third bonding part 1124 have a voltage differential, electrons of the second bonding part 1122 can still be exited to move toward a constant direction. An oxide film cannot provide great capacitance because it has a small thickness. Therefore, conductivity of the oxide film does not change greatly.

In some embodiments, the display panel 100 may further include a storage capacitor C. The capacitor C includes a bottom electrode plate c1 and an upper electrode plate c2 opposite to each other. The bottom electrode plate c1 and the light-shielding layer 103 are disposed on a same layer. The upper electrode plate c2 and the active layer 1021 are disposed on a same layer. That is, the bottom electrode plate c1 and the light-shielding layer 103 are formed by a single mask process. The upper electrode plate c2 and the active layer 1021 are formed by a single mask process. In the present embodiment, the bottom electrode plate c1 and the light-shielding layer 103 are disposed on a same layer, and the upper electrode plate c2 and the active layer 1021 are disposed on a same layer. Therefore, manufacturing steps of the display panel 100 are simplified, and manufacturing cost of the display panel 100 is reduced.

The anode layer 111 includes a first anode sub-layer 1111, a second anode sub-layer 1112, a thin film 1113 for insulating moisture and oxygen, and a third anode sub-layer 1114. The second anode sub-layer 1112 is attached to a side of the first anode sub-layer 1111 away from the TFT structure 102. An orthographic projection of the second anode sub-layer 1112 on the substrate 101 covers an orthographic projection of the first anode sub-layer 1111 on the substrate 101. The third anode sub-layer 1114 is attached to a surface of the second anode sub-layer 1112 away from the first anode sub-layer 1111. The first bonding part 1121 and the first anode sub-layer 1111 may have same material. The material of the first bonding part 1121 includes one of indium tin oxide, indium zinc oxide, Mo, Ni, Nb, or Ti. Preferably, the material of the first bonding part 1121 is Ti. Because TI is a hydrogen storage material. Hydrogen atoms can be stored in interstitial atom of Ti metal, or react with Ti metal to form TiHx (x ranges from 1.5-1.99). After the hydrogen atoms enter the Ti metal, a required activation energy of the hydrogen atoms escaping from the hydrogen atoms will be higher. Therefore, when the hydrogen atoms diffused in the interlayer dielectric layer 106, the passivation layer 109, or the planarization layer 110 at high temperatures, the diffused hydrogen atoms will enter the Ti metal. Furthermore, a layout area of the anode occupies most of a display area. The Ti metal can effectively absorb the hydrogen atoms, thereby reducing the hydrogen atoms diffusing into an active layer of the TFT structure 102, and further improving stability of TFTs.

In the present embodiment, the second anode sub-layer 1112 is attached to a side of the TFT structure 102 away from the first anode sub-layer 1111. Furthermore, an orthographic projection of the first anode sub-layer 1111 on the substrate 101 covers an orthographic projection of the second anode sub-layer 1112 on the substrate. Therefore, water vapor evaporated from the second anode sub-layer 1112 and the planarization layer 1112 is prevented from directly being in contact with hydrogen atoms. The hydrogen atoms diffusing into the TFT structure 102 will result in a failure of the TFT structure 102. Thus, in display panel 100 of the present embodiment, it is not necessary to dispose a first aluminum oxide protective layer and a second aluminum oxide protective layer on the TFT structure 102 to protect the active layer 102, which solves a technical issue of a low yield rate of products and high cost due to aluminum oxide.

The second bonding part 1122 and the second anode sub-layer 1112 may have same material. The material of the second bonding part 1122 includes a mixture of Al, Ni, Cu, and La or an aluminum alloy. The mixture of Al, Ni, Cu, and La is an alloy having a main component of Al and has relatively stable performance, which can solve a dark dot issue of the display panel 100. In addition, aluminum metal will form a dense aluminum oxide thin film under an oxide atmosphere, which can prevent moisture from entering the active layer 1021 of the TFT structure 102, thereby improving stability of the TFT.

The thin film 1113 for blocking moisture and oxygen and the thin film 1123 for insulating moisture and oxygen may have same material. The material of the thin film 1113 for blocking moisture and oxygen and the material of the thin film 1123 for insulating moisture and oxygen may include dense aluminum oxide.

The third anode sub-layer 1114 and the third bonding part 1124 may have same material. The material of the third bonding part 1124 includes indium tin oxide, thereby preventing a thickness of the third anode sub-layer 1114 from being reduced after a water-washing process.

The luminescent functional layer EL further includes a pixel defining layer 113, a luminescent layer 114, and a cathode layer 115. The pixel defining layer 113 is disposed on the anode layer 111. The pixel defining layer 113 includes an opening. The opening exposes a surface of the anode layer 111. The luminescent layer 114 is disposed in the opening. The cathode layer 115 is disposed on a side of the pixel defining layer 113 away from the cathode layer 111, and covers the pixel defining layer 113 and the luminescent layer 114.

The present embodiment provides a display panel. The display panel includes a substrate, a TFT structure, a bonding line, a bonding pad, and a luminescent functional layer. The substrate includes a display area and a pad area. The TFT structure is disposed on the substrate in the display area. The bonding line is disposed on the substrate in the pad area. The bonding pad is disposed on a side of the bonding line away from the substrate. The bonding pad includes a first bonding part, a second bonding part, a thin film for blocking moisture and oxygen, and a third bonding part. The luminescent functional layer is disposed on a side of the TFT structure away from the substrate. Material of the bonding line is commonly copper which is easy to be oxidized, affecting conductivity performance. Therefore, the bonding line cannot be directly used as a metal pad. In the present embodiment, the bonding pad is disposed on the bonding line. Because the bonding pad includes the thin film for blocking moisture and oxygen, one mask process can be omitted, reducing manufacturing cost of the display panel. Furthermore, an orthographic projection of a first anode sub-layer on the substrate covers an orthographic projection of a second anode sub-layer on the substrate. Therefore, the second anode sub-layer is prevented from being directly in contact with a planarization layer to generate hydrogen atoms and result in a failure of the TFT structure. Thus, in the display panel of the present disclosure, it is not necessary to dispose a first aluminum oxide protective layer and a second aluminum oxide protective layer to protect the active layer 1021, thereby solving a technical issue of a low yield rate of products due to an introduction of aluminum oxide.

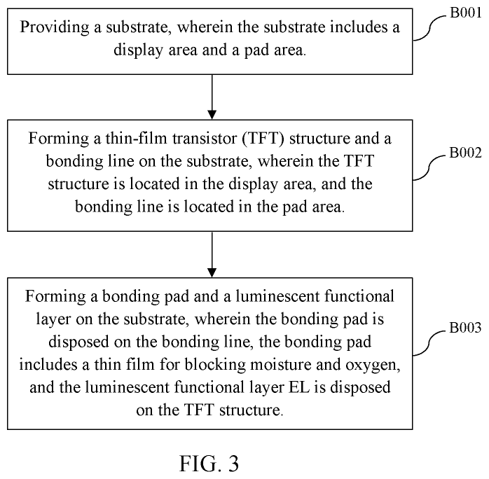

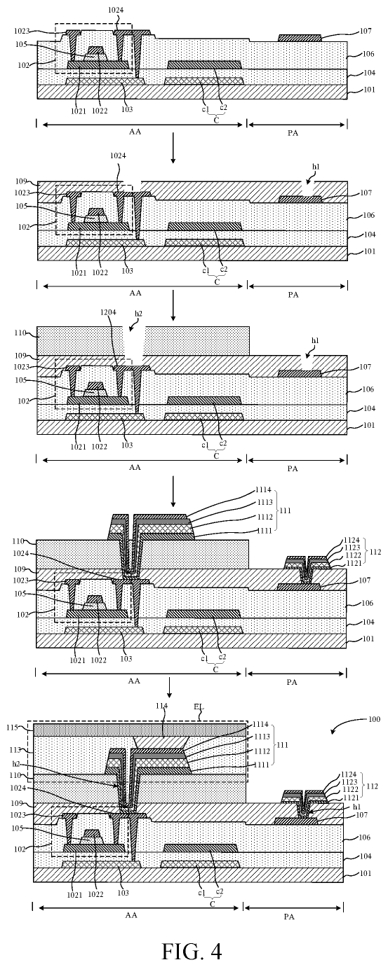

Correspondingly, the present embodiment further provides a method of manufacturing a display panel. Please refer to FIG. 3 and FIG. 4. FIG. 3 is a flowchart showing steps of the method of manufacturing the display panel provided by the present embodiment. FIG. 3 is a schematic view showing the method of manufacturing the display panel provided by the present embodiment. The method of manufacturing the display panel includes a plurality of following steps:

Step B001, providing a substrate 101, wherein the substrate 101 includes a display area AA and a pad area PA.

In some embodiments, the substrate 101 may be a glass substrate 101.

After the step B001, the method includes a plurality of following steps:
depositing a metal layer on the substrate 101, and performing a patterning process to form a light-shielding layer 103; and
depositing a buffer layer 104 on the substrate 101.

Step B002, forming a TFT structure 102 and a bonding line 107 on the substrate 101, wherein the TFT structure 102 is located in the display area AA, and the bonding line 107 is located in the pad area PA.

Specifically, a metal oxide semiconductor material is deposited on the buffer layer, and is patterned to form an active layer 1021.

An insulating layer and a conductive metal layer are sequentially formed on the active layer 1021. A gate 1022 is formed by etching during a lithographic process. Then a gate insulating layer 105 is formed by etching according to the self-aligned gate 1022. The gate insulating layer 105 only exists below the gate 1022, the insulating layer in other places is etched completely.

An entire surface is performed with a plasma process. Electrical resistance of a doping area, which is the active layer 1021 without the gate 1022 and the gate insulating layer 105 protectively disposed thereon, is significantly reduced after the plasma process. The active layer 1021 corresponding to the gate 1022 retains semiconductor properties and is used as a channel of the active layer 1021.

An interlayer dielectric layer 106 is formed on the substrate 101, A first contact opening, a second contact opening, and a third contact opening are formed by etching during a lithographic process.

A conductive metal layer is deposited on the interlayer dielectric layer 106. Then, a lithographic process and an etching process are performed to form a source 1023, a drain 1024, and a bonding line 107. The active layer 1021, the gate 1022, the source 1023, and the drain 1024 constitute the TFT structure 102.

A passivation layer 109 is formed on the interlayer dielectric layer 106, and a first opening h1 is formed by etching. The first opening h1 exposes part of a surface of the bonding line 107 away from the substrate 101.

A planarization layer 110 is formed on the passivation layer 109 and is patterned. A second opening h2 is formed by etching. The planarization layer 110 corresponds to the display area AA.

Step B003, forming a bonding pad 112 and a luminescent functional layer EL on the substrate 101. The bonding pad 112 is disposed on the bonding line 107. The bonding pad 112 includes a thin film 1123 for blocking moisture and oxygen. The luminescent functional layer EL is disposed on the TFT structure 102.

The luminescent functional layer EL includes an anode layer 111. The step of forming the bonding pad 112 and the luminescent functional layer EL on the substrate 101 includes a following step:
forming the anode layer 111 and the bonding pad 112 on the substrate 101 by a single mask process. The anode is connected to the TFT structure 102. The bonding pad 112 is disposed on a side of the bonding line 107 away from the substrate 101. The bonding pad 112 includes a first bonding part 1121, a second bonding part 1122, a thin film 1123 for blocking moisture and oxygen, and a third bonding part 1124. The anode layer 111 includes a first anode sub-layer 1111, a second anode sub-layer 1112, a thin film 1113 for insulating moisture and oxygen, and a third anode sub-layer 1114 sequentially disposed on the TFT structure 102.

In some embodiments, the step B003 includes a plurality of following steps:
sequentially forming a first conductive metal layer and a second conductive metal layer on the substrate 101; and
oxidizing a surface of the second conductive metal layer away from the first conductive metal layer to form a blocking layer.

Specifically, the substrate, which the first conductive metal layer and the second conductive metal layer are already formed thereon, is disposed in an isolated vacuum chamber. Then, the side of the second conductive metal layer away from the first conductive metal layer are oxidized by oxygen to form a dense metal oxide thin film (the blocking layer).

A third conductive metal layer is formed on the blocking layer.

The first conductive metal layer, the second conductive metal layer, the blocking layer, and the third conductive metal layer are processed by a same mask process to sequentially form the first anode sub-layer 1111, the second anode sub-layer 1112, the thin film 1113 for blocking moisture and oxygen, and the third anode sub-layer 1114 on the TFT structure 102 and sequentially form the first bonding part 1121, the second bonding part 1122, the thin film 1123 for insulating moisture and oxygen, and the third bonding part 1124 on the bonding line 107.

The step of forming the bonding pad 112 and the luminescent functional layer EL on the substrate 101 further includes a following step: forming the luminescent layer 114 on the anode layer 111, and forming a cathode layer 115 on the luminescent layer 114. The anode layer 111, the luminescent layer 114, and the cathode layer 115 constitute the luminescent functional layer EL.

An embodiment of the present disclosure provides a method of manufacturing a display panel. The method includes following steps: providing a substrate, wherein the display panel includes a display area and a bonding area; forming a TFT structure and a bonding line on the substrate, wherein the TFT structure is disposed in the display area, and the bonding line is disposed in the bonding area; forming an anode layer and a bonding pad on the substrate by a single mask process, wherein the TFT structure is connected to the anode, the bonding pad is disposed on a side of the bonding line away from the substrate, and the bonding pad includes a first bonding part, a second bonding part, a thin film for blocking moisture and oxygen, and a third bonding part; forming a luminescent layer on the anode layer; and forming a cathode layer on the luminescent layer, wherein the anode layer, the luminescent layer, and the cathode layer constitute a luminescent functional layer. In the method provided by the present disclosure, the bonding pad is disposed on the bonding line, and the bonding pad and the bonding line constitute a metal pad to bond driving chips configured to process information of the display panel. Furthermore, because a surface of the bonding line is covered by the bonding pad, the bonding line can be prevented from being corroded. Moreover, the anode layer and the bonding layer can be formed by a single mask process. Therefore, steps of manufacturing the display panel are simplified, and manufacturing cost of the display panel is reduced.

In summary, the present disclosure has been described with preferred embodiments thereof. The preferred embodiments are not intended to limit the present disclosure, and it is understood that many changes and modifications to the described embodiments can be carried out without departing from the scope and the spirit of the disclosure that is intended to be limited only by the appended claims.

What is claimed is:

1. A display panel, comprising:
a substrate, wherein the substrate comprises a display area and a pad area;
a thin-film transistor (TFT) structure disposed on the substrate, wherein the TFT structure is located in the display area;
a bonding line disposed on the substrate, wherein the bonding line is located in the pad area;
a bonding pad disposed on a side of the bonding line away from the substrate, wherein the bonding pad comprises a thin film for blocking moisture and oxygen; and
a luminescent functional layer disposed on a side of the TFT structure away from the substrate.

2. The display panel of claim 1, wherein the luminescent functional layer comprises an anode layer, the anode layer is connected to the TFT structure, and the anode layer and the bonding pad have same material.

3. The display panel of claim 2, wherein the bonding pad comprises first a bonding part, a second bonding part, and a third bonding part, the first bonding part is disposed on a side of the bonding line close to the TFT structure, the second bonding part is disposed on a side of the first bonding part away from the bonding line, the thin film for blocking moisture and oxygen is disposed on a side of the second bonding part away from the first bonding part, the third bonding part is disposed on a side of the thin film for blocking moisture and oxygen away from the second bonding part, and the anode layer comprises a first anode sub-layer, a second anode sub-layer, a thin film for insulating moisture and oxygen, and a third anode sub-layer sequentially disposed on the TFT structure.

4. The display panel of claim 3, wherein an orthographic projection of first anode sub-layer on the substrate covers an orthographic projection of the second anode sub-layer on the substrate.

5. The display panel of claim 3, wherein the first bonding part and the first anode sub-layer comprise same material, and the material of the first bonding part comprises one of indium tin oxide, indium zinc oxide, Mo, Ni, Nb, or Ti.

6. The display panel of claim 3, wherein the second bonding part and the second anode sub-layer comprise same material, and the material of the second bonding part comprises a mixture of Al, Ni, Cu, and LA, or comprises an Al alloy.

7. The display panel of claim 3, wherein the third anode sub-layer and the third bonding part comprise same material, and the material of the third bonding part comprises indium tin oxide.

8. The display panel of claim 1, wherein the material of the thin film for blocking moisture and oxygen and the material of the thin film for insulating moisture and oxygen comprise metal oxide.

9. The display panel of claim 2, wherein the display panel comprises a passivation layer, a planarization layer, a first opening, and a second opening, the passivation layer is disposed on the substrate, the planarization layer is disposed on a side of the passivation layer away from the substrate, the first opening penetrates the passivation layer and exposes at least part of a surface of the bonding line away from the substrate, the bonding pad is connected to the bonding line by the first opening, the second opening penetrates the planarization layer and the passivation layer and exposes part of a surface of the TFT structure, and the anode layer is connected to the TFT structure by the second opening.

10. The display panel of claim 9, wherein the TFT structure comprises an active layer, a gate, a source, and a gate, and the bonding line, the source, and the drain are disposed on a same layer.

11. A method of manufacturing a display panel, comprising a plurality of following steps:
providing a substrate, wherein the substrate comprises a display area and a pad area;
forming a thin-film transistor (TFT) structure and bonding line on the substrate, wherein the TFT structure is located in the display panel, and the bonding line is located in the pad area; and
forming a bonding pad and a luminescent functional layer on the substrate, wherein the bonding pad is disposed on the bonding line, the bonding pad comprises a thin film for blocking moisture and oxygen, and the luminescent functional layer is disposed on the TFT structure.

12. The method of claim 11, wherein the luminescent functional layer comprises an anode layer, and the step of forming the bonding pad and the luminescent functional layer comprises a following step:
forming the anode layer and the bonding pad on the substrate by a single mask process, wherein the anode layer is connected to the TFT structure, the bonding pad is disposed on a side of the bonding line away from the substrate, the bonding pad comprises a first bonding part, a second bonding part, and the third bonding part, the anode layer comprises a first anode sub-layer, a second anode sub-layer, a thin film for insulating moisture and oxygen, and a third anode sub-layer sequentially disposed on the TFT structure.

13. The method of claim 12, wherein the step of forming the anode layer and the bonding pad on the substrate by the single mask process comprises a plurality of following steps:
sequentially forming a first conductive metal layer and a second conductive metal layer on the substrate;
oxidizing a surface of the second conductive metal layer away from the first conductive metal layer to form a blocking layer;
forming a third conductive metal layer on the blocking layer; and
processing the first conductive metal layer, the second conductive metal layer, the blocking layer, and the third conductive blocking layer by a single mask process to form the first anode sub-layer, the second anode sub-layer, the thin film for blocking moisture and oxygen, and the third anode sub-layer sequentially stacked on the thin-film structure and the first bonding part, the second bonding part, the thin-film for insulating moisture and oxygen, and the third bonding part sequentially stacked on the bonding line.
